(19) United States
(12) Patent Application Publication
(10) Pub. No.: US 2015/0289411 A1
(43) Pub. Date: Oct. 8, 2015

(54) INVERTER DEVICE

(71) Applicant: KABUSHIKI KAISHA TOYOTA JIDOSHOKKI, Kariya-shi, Aichi-ken (JP)

(72) Inventors: Yasunobu Kamiya, Kariya-shi (JP); Naoki Higashikawa, Kariya-shi (JP)

(73) Assignee: KABUSHIKI KAISHA TOYOTA JIDOSHOKKI, Kariya-shi, Aichi-ken (JP)

(21) Appl. No.: 14/646,969

(22) PCT Filed: Oct. 24, 2013
(86) PCT No.: PCT/JP2013/078770

§ 371 Date: May 22, 2015

(30) Foreign Application Priority Data
Nov. 29, 2012 (JP) 2012-261192

(51) Int. Cl. H05K 7/20

(52) U.S. Cl. CPC H05K 7/20263

(57) ABSTRACT

An inverter device includes: a housing; semiconductor modules; a first heat exchanger having a first passage, wherein a heat generating component is thermally coupled to the first heat exchanger; a second heat exchanger provided inside the housing; a supply port connected to a supply pipe for supplying coolant; a discharge port connected to a discharge pipe, wherein the discharge pipe discharges coolant from the first heat exchanger or the second heat exchanger to a coolant supply source; a discharge port connected to a discharge pipe, which discharges coolant from the first heat exchanger or the second heat exchanger to the coolant supply source; and communication lines which allow the first passage and a second passage to communicate with each other.

### TECHNICAL FIELD

The present invention relates to an inverter device having a semiconductor module accommodated in a housing.

### BACKGROUND ART

As a device for cooling a heat generating component using coolant flowing in a passage formed in a case, a heat generating element cooling structure described in Japanese Laid-Open Patent Publication No. 2003-101277, for example, is known.

The cooling structure described in the aforementioned document is configured by a power module, an inverter case, and a DC-DC converter. Space for accommodating a heat generating element mounted on the power module and a peripheral circuit of the heat generating element is formed on a side corresponding to the upper surface of the inverter case. A side wall is formed in an outer peripheral portion of the lower surface of the inverter case. An attachment substrate is attached to the side wall to form a coolant passage on the side corresponding to the lower surface of the inverter case. The DC-DC converter is attached to the attachment substrate. Coolant flows in the coolant passage, thus cooling the power module and the DC-DC converter.

### PRIOR ART DOCUMENTS

### Patent Documents

Patent Document 1: Japanese Laid-Open Patent Publication No. 2003-101277

### SUMMARY OF THE INVENTION

### Problems that the Invention is to Solve

However, the cooling structure described in Japanese Laid-Open Patent Publication No. 2003-101277 may cause deficiencies in cooling performance for the heat generating element.

### Means for Solving the Problems

Accordingly, it is an objective of the present invention to provide an inverter device capable of limiting deficiencies in cooling performance.

In accordance with one aspect of the present disclosure, an inverter device is provided that includes a housing, a semiconductor module accommodated in the housing, a first heat exchanger, a second heat exchanger, a supply port, a discharge port, and a communication line. The first heat exchanger has a first passage defined by an outer surface of the housing and a passage forming member that covers at least a portion of the outer surface. The first heat exchanger is thermally coupled to a heat generating component. The second heat exchanger is arranged in the housing, wherein the second heat exchanger has a second passage stacked on the first passage and is thermally coupled to the semiconductor module. The supply port is connected to a supply pipe for supplying coolant from a coolant supply source to the first heat exchanger or the second heat exchanger. The discharge port is connected to a discharge pipe. The discharge pipe discharges coolant from the first heat exchanger or the second heat exchanger to the coolant supply source. The communication line allows the first passage and the second passage to communicate with each other.

In this form, when the semiconductor module generates heat, heat exchange occurs between thermal medium flowing in the second passage, which is arranged in a case, and the semiconductor module, thus cooling the semiconductor module. When the heat generating component generates heat, heat exchange occurs between coolant flowing in the first passage and the heat generating component, thus cooling the heat generating component. By providing a heat exchanger for cooling the semiconductor module and a heat exchanger for cooling the heat generating component separately, deficiencies in cooling performance for the semiconductor module and the heat generating component are limited.

According to one form of the disclosure, the communication line includes a first communication line and a second communication line different from the first communication line. One of the first passage and the second passage has a supply passage and a discharge passage, wherein the supply passage has the supply port and is connected to the first communication line, and the discharge passage has the discharge port and is connected to the second communication line. The other one of the first passage and the second passage and the discharge passage have a flow-reversing structure.

In this form, the supply port and the discharge port are arranged in one of the first passage and the second passage. This provides a simple sealing structure compared to a case in which the supply port and the discharge port are arranged separately. Since the flow-reversing structure allows adjacent arrangement of the supply pipe and the discharge pipe, connection of the coolant supply source to the supply pipe and the discharge pipe is facilitated.

According to one form of the disclosure, the first passage has a supply passage that has the supply port and is connected to the first communication line and a discharge passage that has the discharge port and is connected to the second communication line. The second passage and the discharge passage have a flow-reversing structure.

In this form, the supply port and the discharge port are arranged in the first passage formed by the outer surface of the housing and the passage forming member. This facilitates connection of the first passage to the coolant supply source.

According to one form of the disclosure, the first heat exchanger and the second heat exchanger are formed separately.

This form facilitates joint of the semiconductor module to the second heat exchanger compared to a case in which the first heat exchanger and the second heat exchanger are arranged integrally with each other.

According to one form of the present disclosure, the first passage has a first fin molded integrally with the first heat exchanger through die casting. The second passage has a second fin that is formed separately from the second heat exchanger.

In this form, the fin pitch of the second fin is small compared to the fin pitch of the first fin, which is formed through die casting. To cool the semiconductor module, the second heat exchanger needs to have a higher cooling performance than the first heat exchanger. The first heat exchanger does not need a cooling performance comparable to that of the second heat exchanger. Therefore, the cooling performance of the second heat exchanger is improved by providing the fin of the second heat exchanger separately to reduce the fin pitch. In contrast, the first fin of the first heat exchanger is molded integrally with the first heat exchanger through die casting. The first fin is thus manufactured simultaneously with the first heat exchanger. This facilitates manufacture of the first fin.

According to one form of the present disclosure, the heat generating component includes an electronic component joined to a metal base substrate. The metal base substrate functions also as the passage forming member.

In this form, the metal base substrate is used also as the passage forming member. This makes it unnecessary to prepare a separate passage forming member. As a result, the first passage is defined without increasing the number of the components.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The features of the present disclosure that are believed to be novel are set forth with particularity in the appended claims. The disclosure, together with objects and advantages thereof, may best be understood by reference to the following description of the presently preferred embodiments together with the accompanying drawings in which:

FIG. 1 is a cross-sectional view showing an inverter device according to one embodiment;

FIG. 2 is a cross-sectional view showing the inverter device according to the embodiment;

FIG. 3A is a plan view showing a power module of the embodiment as viewed from above;

FIG. 3B is a plan view showing the power module of the embodiment as viewed from below;

FIG. 4 is a circuit diagram representing the electric configuration of the inverter device according to the embodiment; and

FIG. 5 is a cross-sectional view showing another example of the inverter device.

### MODES FOR CARRYING OUT THE INVENTION

An inverter device according to one embodiment will now be described.

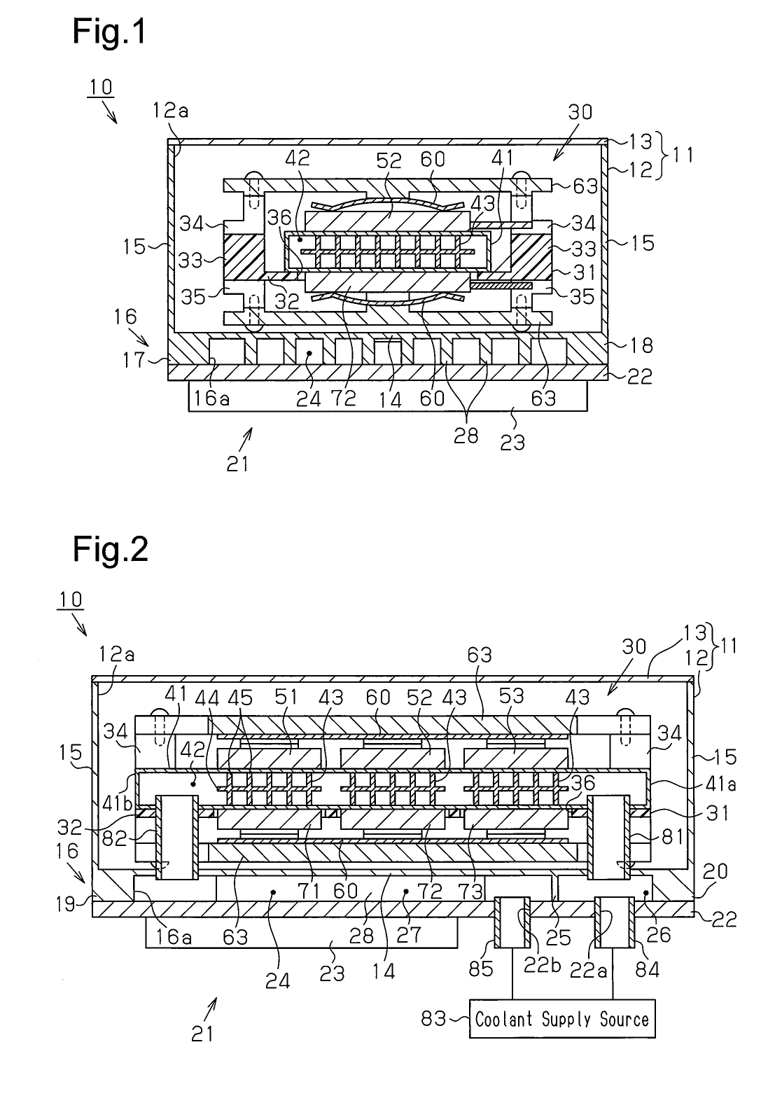

As shown in FIGS. 1 and 2, an inverter device 10 has a power module 30, which is arranged in a housing 11. The housing 11 is formed by a rectangular-box-like main body 12 for accommodating the power module 30 and a top plate 13 for closing an opening 12a of the main body 12. The main body 12 has a flat rectangular bottom plate 14 and four side walls 15, which are arranged upright from outer peripheries of the bottom plate 14. The opening 12a is formed by being surrounded by the side walls 15. The top plate 13 is arranged at the distal ends of the side walls 15. A first heat exchanger 16 is arranged in a bottom portion of the housing 11. The main body 12 of the present embodiment is made of, for example, an aluminum alloy and manufactured through die-casting. FIG. 1 is viewed in a direction turned by 90 degrees with respect to the direction in which FIG. 2 is viewed.

The bottom plate 14 has rectangular parallelepiped-like projections 17, 18, 19, 20, which are formed at outer periphery of the surface (an outer surface of the housing 11) opposite to the side from which the side walls 15 project. Hereinafter, the projections 17, 18, which are arranged in the transverse direction of the bottom plate 14, will be referred to as the first projections 17, 18. The projections 19, 20, which are arranged in the longitudinal direction of the bottom plate 14, will be referred to as the second projections 19, 20.

A DC-DC converter 21 is arranged at the outer side of the bottom plate 14. The DC-DC converter 21 is configured by mounting an electronic component 23 serving as a heat generating component, such as a switching element, on a metal base substrate 22. The metal base substrate 22 has a flat rectangular shape. The longitudinal dimension and the transverse dimension of the metal base substrate 22 are equal to the longitudinal dimension and the transverse dimension of the bottom plate 14, respectively. The metal base substrate 22 is arranged at the distal ends of the projections 17, 18, 19, 20. The metal base substrate 22 closes an opening 16a, which is formed by being surrounded by the projections 17, 18, 19, 20. A first passage 24, in which coolant flows, is defined by the first projections 17, 18, the second projections 19, 20, and the metal base substrate 22. In the present embodiment, the metal base substrate 22 functions as a passage forming member, which defines the first passage 24 by covering the corresponding outer surface of the housing 11. In the embodiment, the bottom plate 14 of the housing 11 and the metal base substrate 22 form the first heat exchanger 16.

A partition wall 25, which extends from the first projection 17 to the other first projection 18, is arranged on the outer surface of the bottom plate 14. The partition wall 25 is located at the side corresponding to the second projection 20 in the longitudinal direction of the bottom plate 14. That is, the partition wall 25 is arranged between the second projections 19 and 20 at a position closer to the second projection 20 than the other second projection 19. The partition wall 25 divides the first passage 24 into a supply passage 26 and a discharge passage 27, which are adjacent to each other in the longitudinal direction of the bottom plate 14. The supply passage 26 is arranged at the side corresponding to the second projection 20 with respect to the partition wall 25. The discharge passage 27 is provided at the side corresponding to the second projection 19 with respect to the partition wall 25. That is, the supply passage 26 is arranged between the partition wall 25 and the second projection 20 and the discharge passage 27 is located between the partition wall 25 and the second projection 19. Since the partition wall 25 is arranged at the side corresponding to the second projection 20, the dimension of the supply passage 26 in the longitudinal direction of the bottom plate 14 is smaller than the dimension of the discharge passage 27 in the longitudinal direction of the bottom plate 14. A supply port 22a having an opening in the supply passage 26 and a discharge port 22b having an opening in the discharge passage 27 are formed in the metal base substrate 22.

A plurality of plate-like first fins 28, each of which extends in the longitudinal direction of the bottom plate 14, are formed at the outer surface of the bottom plate 14 and spaced apart in the transverse direction of the bottom plate 14. The first fins 28 are formed between the second projection 19 and the partition wall 25. That is, the first fins 28 are arranged in the discharge passage 27. The first fins 28 are molded integrally with the main body 12 through die-casting.

The power module 30 includes a seat 31. The seat 31 is fixed in the housing 11 by means of a non-illustrated support portion. The seat 31 includes a flat rectangular base portion 32. Rectangular parallelepiped-like insulation bases 33, which project in the thickness direction of the base portion 32, are arranged at opposite transverse end portions (opposite left and right end portions as viewed in FIG. 1) of the base portion 32.

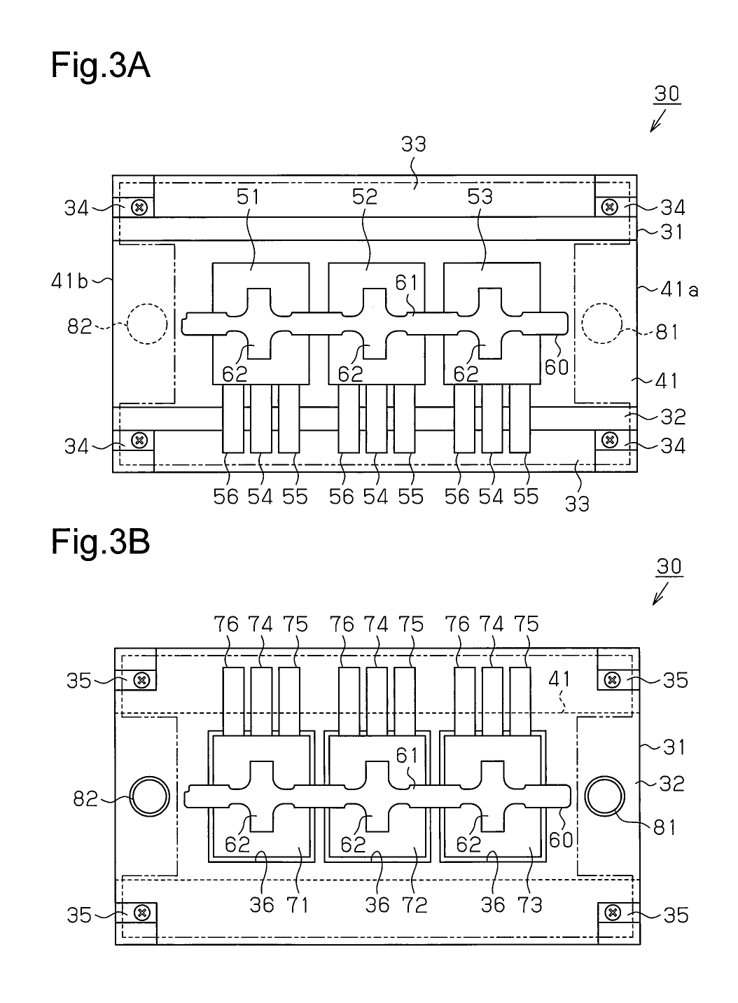

With reference to FIGS. 3A and 3B, protrusions 34 are formed at opposite longitudinal end portions of each of the insulation bases 33. The base portion 32 has a first surface and a second surface, which is opposite to the first surface. The insulation bases 33 are arranged on the first surface of the base portion 32. Protrusions 35 are arranged at the four corners of the second surface of the base portion 32. Three rectangular through holes 36 are formed in the base portion 32 and spaced apart in the longitudinal direction of the base portion 32.

As illustrated in FIGS. 1 and 2, a cooling device 41 serving as a second heat exchanger is arranged on the surface (the first surface) of the base portion 32 on which the insulation bases 33 are provided. The cooling device 41 is shaped like a rectangular parallelepiped and a second passage 42 is formed in the cooling device 41. The cooling device 41 is stacked on the first heat exchanger 16. The second passage 42 is thus stacked on the first passage 24.

Referring to FIG. 2, three fin units 43 are arranged in the cooling device 41 (the second passage 42) and spaced apart in the longitudinal direction of the cooling device 41. Each of the fin units 43 is configured by forming pin-like second fins 45 on opposite surfaces of a flat rectangular base portion 44. Each fin unit 43 is provided by brazing the distal end surfaces of the second fins 45 onto inner surfaces of the cooling device 41. The fin pitch of the second fins 45 is small compared to the fin pitch of the first fins 28.

As illustrated in FIG. 3A, the cooling device 41 has a first surface facing the base portion 32 and a second surface, which is opposite to the first surface. First semiconductor modules 51, 52, 53 are joined to the second surface of the cooling device 41. The first semiconductor modules 51 to 53 are arranged and spaced apart in the longitudinal direction of the cooling device 41. A first positive-side input terminal 54 electrically connected to the positive terminal of a power supply, a first negative-side input terminal 55 electrically connected to the negative terminal of the power supply, and a first output terminal 56 electrically connected to a load are arranged in each of the first semiconductor modules 51 to 53.

The first semiconductor modules 51 to 53 each have a first surface facing the cooling device 41 and a second surface, which is opposite to the first surface. A leaf spring 60 is arranged on the second surfaces of the first semiconductor modules 51 to 53. The leaf spring 60 is formed by substantially flat rectangular bodies 61 and holding portions 62, which are arranged in the longitudinal direction of each of the bodies 61 and extended from three portions between the bodies 61 toward the opposite transverse sides of the bodies 61. More specifically, the leaf spring 60 is formed by the bodies 61 each having a substantially flat rectangular shape and the three holding portions 62. The holding portions 62 are each located between the corresponding adjacent pair of the bodies 61. Each of the holding portions 62 extends in the transverse direction of each body 61.

A plate member 63 is fixed to the protrusions 34, which are arranged on the insulation base 33. The plate member 63 presses the bodies 61 of the leaf spring 60. This presses the holding portions 62 against the associated first semiconductor modules 51 to 53 and joins the first semiconductor modules 51 to 53 to the cooling device 41.

With reference to FIG. 3B, second semiconductor modules 71, 72, 73 are each inserted in one of the through holes 36, which are formed in the base portion 32. The second semiconductor modules 71 to 73, which are inserted in the through holes 36, are joined to the first surface (the surface facing the base portion 32) of the cooling device 41, which is opposite to the second surface to which the first semiconductor modules 51 to 53 are joined. The second semiconductor modules 71 to 73 are arranged and spaced apart in the longitudinal direction of the cooling device 41. A second positive-side input terminal 74 electrically connected to the positive terminal of the power supply, a second negative-side input terminal 75 electrically connected to the negative terminal of the power supply, and a second output terminal 76 electrically connected to a load are arranged in each of the second semiconductor modules 71 to 73.

The second semiconductor modules 71 to 73 are each joined to the cooling device 41 like the first semiconductor modules 51 to 53. A leaf spring 60 presses the second semiconductor modules 71 to 73 against the cooling device 41. A plate member 63, which presses the leaf spring 60, is fixed to the protrusions 35. The second semiconductor modules 71 to 73 are joined to the cooling device 41 through the leaf spring 60 like the first semiconductor modules 51 to 53.

In the present embodiment, the first positive-side input terminal 54 of each of the first semiconductor modules 51 to 53 is electrically connected to the second positive-side input terminal 74 of the corresponding one of the second semiconductor modules 71 to 73 through a non-illustrated bus bar. Likewise, the first negative-side input terminal 55 of each of the first semiconductor modules 51 to 53 is electrically connected to the second negative-side input terminal 75 of the corresponding one of the second semiconductor modules 71 to 73 through a non-illustrated bus bar. The first output terminal 56 of each of the first semiconductor modules 51 to 53 is electrically connected to the second output terminal 76 of the corresponding one of the second semiconductor modules 71 to 73. That is, in the present embodiment, each of the first semiconductor modules 51 to 53 and the corresponding one of the second semiconductor modules 71 to 73 are connected in parallel. Each first semiconductor module 51 to 53 and the corresponding second semiconductor module 71 to 73 configure an inverter.

Each of the fin units 43 is arranged in a section of the second passage 42 corresponding to the position between the corresponding one of the first semiconductor modules 51 to 53 and the associated one of the second semiconductor modules 71 to 73.

As shown in FIG. 2, a first vertical pipe 81 serving as a first communication line is arranged at a side corresponding to a first longitudinal end portion 41a of the cooling device 41. The first vertical pipe 81 is inserted through the bottom plate 14 and extends to the supply passage 26. The first vertical pipe 81 connects the supply passage 26 and the second passage 42 to each other.

A second vertical pipe 82 serving as a second communication line is arranged at a side corresponding to a second longitudinal end portion 41b of the cooling device 41. The second vertical pipe 82 is inserted through the bottom plate 14 and extends to the discharge passage 27. The second vertical pipe 82 connects the discharge passage 27 and the second passage 42 to each other.

A supply pipe 84, which is connected to a coolant supply source 83 and supplies coolant from the coolant supply source 83 to the supply passage 26, is arranged in the supply passage 26. The supply pipe 84 is connected to the supply port 22a, which is provided in the metal base substrate 22.

A discharge pipe 85 is arranged in the discharge passage 27. The discharge pipe 85 discharges the coolant from the second passage 42 to the exterior of the discharge passage 27, thus re-supplying the coolant to the coolant supply source 83. The discharge pipe 85 is connected to the discharge port 22b, which is provided in the metal base substrate 22. The discharge pipe 85 is located closer to the supply pipe 84 than the second vertical pipe 82. As a result, the second passage 42 and the discharge passage 27 have a flow-reversing structure such that the coolant in the second passage 42 proceeds from the first vertical pipe 81 to the second vertical pipe 82 and that the coolant in the discharge passage 27 proceeds from the second vertical pipe 82 to the discharge pipe 85.

The electric configuration of the inverter device 10 will hereafter be described.

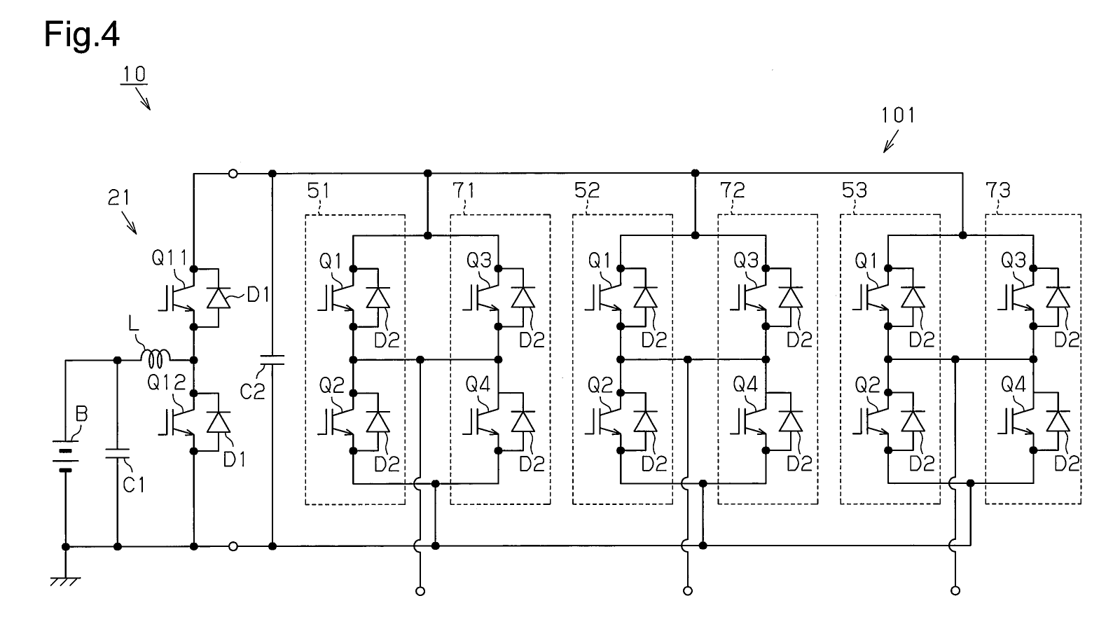

With reference to FIG. 4, the inverter device 10 of the present embodiment is installed in, for example, a hybrid vehicle or an electric vehicle to convert DC power supplied from a battery B to AC power and output the AC power to a load. The inverter device 10 includes an inverter 101 and the DC-DC converter 21. The inverter 101 is configured by the first semiconductor modules 51 to 53 and the second semiconductor modules 71 to 73. The DC-DC converter 21 is configured by the electronic component 23 mounted on the metal base substrate 22.

The DC-DC converter 21 is arranged between the battery B and the inverter 101. The DC-DC converter 21 has switching elements Q11, Q12. As the switching elements Q11, Q12, power semiconductor elements such as insulated gate bipolar transistors (IGBTs) or a power metal oxide semiconductor field effect transistors (MOSFETs) are employed.

The switching elements Q11, Q12 are connected in series between a power supply line of the inverter 101 and an earth line. The collector of the switching element Q11 is connected to the power supply line. The emitter of the switching element Q12 is connected to the earth line and the negative terminal of the battery B. A connecting point between the emitter of the switching element Q11 and the collector of the switching element Q12 is connected to a first end of a reactor L. A second end of the reactor L is connected to the positive terminal of the battery B. A diode D1 is connected to and arranged between the collector and the emitter of the switching element Q11 such that electric current flows from the emitter to the collector. Another diode D1 is connected to and arranged between the collector and the emitter of the switching element Q12 such that electric current flows from the emitter to the collector. As a result, the electronic component 23 includes at least the switching elements Q11 and Q12, the diodes D1, and the reactor L.

A low-voltage capacitor C1 is connected to an input terminal of the DC-DC converter 21 (a connecting terminal with respect to the battery B). A high-voltage capacitor C2 is connected to a connecting terminal with respect to the inverter 101, which is an output terminal of the DC-DC converter 21.

Each of the first semiconductor modules 51 to 53 includes a first switching element Q1 and a second switching element Q2. Each of the second semiconductor modules 71 to 73 includes a third switching element Q3 and a fourth switching element Q4. As the switching elements Q1, Q2, Q3, Q4, power semiconductor elements such as insulated gate bipolar transistors (IGBTs) or power metal oxide semiconductor field effect transistors (MOSFETs) are employed.

Each of the first switching elements Q1 is connected in series with the corresponding one of the second switching elements Q2. Each of the third switching elements Q3 is connected in series with the corresponding one of the fourth switching elements Q4. A diode D2 is connected in parallel with each of the switching elements Q1 to Q4.

In each of the first semiconductor modules 51 to 53, the connecting point between the two switching elements Q1 and Q2 is connected to the first output terminal 56. In each of the second semiconductor modules 71 to 73, the connecting point between the two switching elements Q3 and Q4 is connected to the second output terminal 76. Each of the first output terminals 56 and the corresponding one of the second output terminals 76 are connected to each other through a bus bar or the like and electrically connected to a load.

The collector of each of the first switching elements Q1 is connected to the corresponding one of the first positive-side input terminals 54. The collector of each of the third switching elements Q3 is connected to the corresponding one of the second positive-side input terminals 74. Each of the first positive-side input terminals 54 and the corresponding one of the second positive-side input terminals 74 are connected to each other through a bus bar or the like and to the positive terminal of the battery B through the DC-DC converter 21.

The emitter of each of the second switching elements Q2 is connected to the corresponding one of the first negative-side input terminals 55. The emitter of each of the fourth switching elements Q4 is connected to the corresponding one of the second negative-side input terminals 75. Each of the first negative-side input terminals 55 and the corresponding one of the second negative-side input terminals 75 are connected to each other through a bus bar or the like and to the negative terminal of the battery B through the DC-DC converter 21. The pair of the first semiconductor module 51 and the second semiconductor module 71, the pair of the first semiconductor module 52 and the second semiconductor module 72, and the pair of the first semiconductor module 53 and the second semiconductor module 73 each configure a pair of upper and lower arms corresponding to one phase of the inverter 101. The first semiconductor modules 51 to 53 and the second semiconductor modules 71 to 73 configure upper and lower arms corresponding to three phases. In this manner, the inverter device of the present embodiment configures a three-phase inverter device.

Operation of the inverter device 10 will now be described.

When the inverter device 10 is activated, the first semiconductor modules 51 to 53, the second semiconductor modules 71 to 73, the metal base substrate 22, and the electronic component 23 generate heat.

Coolant is supplied from the coolant supply source 83 to the supply passage 26. After having been supplied to the supply passage 26, the coolant is supplied to the second passage 42 via the first vertical pipe 81. The coolant, which has been supplied to the second passage 42, flows in the second passage 42 to cool the first semiconductor modules 51 to 53 and the second semiconductor modules 71 to 73, which are thermally coupled to the opposite surfaces of the cooling device 41.

After having flowed in the second passage 42, the coolant is supplied to the discharge passage 27 via the second vertical pipe 82. The coolant, which has been supplied to the discharge passage 27, flows in the discharge passage 27 to cool the metal base substrate 22 and the electronic component 23, which is mounted on the metal base substrate 22.

The discharge pipe 85, which is arranged in the discharge passage 27, is located at the side corresponding to the supply pipe 84 with respect to the second vertical pipe 82. That is, the discharge pipe 85 is closer to the supply pipe 84 than the second vertical pipe 82. The flow direction of the coolant in the second passage 42 is thus opposite to the flow direction of the coolant in the discharge passage 27. That is, when coolant is supplied from the second vertical pipe 82 into the discharge passage 27 after having flowed in the second passage 42, the flow of coolant is reversed to proceed to the supply pipe 84 and then flows in the discharge passage 27.

In the present embodiment, the first fins 28 are molded integrally with the main body 12 through die casting. On the other hand, the fin units 43 are arranged separately from the cooling device 41. In the case of the first fins 28 formed through die casting, it is difficult to provide a small fin pitch for the first fins 28. The fin pitch of the second fins 45 of each fin unit 43 is small compared to the fin pitch of the first fins 28. This improves cooling efficiency for the first semiconductor modules 51 to 53 and the second semiconductor modules 71 to 73, which are joined to the cooling device 41, compared to cooling efficiency for the electronic component 23, which is thermally coupled to the first heat exchanger 16 (the housing 11).

The above described embodiment achieves the following advantages.

(1) The cooling device 41 is arranged in the housing 11. The first semiconductor modules 51 to 53 and the second semiconductor modules 71 to 73 are thermally coupled to the cooling device 41. The first heat exchanger 16 is arranged in the exterior of the housing 11. The DC-DC converter 21 is thermally coupled to the first heat exchanger 16. The cooling device 41, which cools the first semiconductor modules 51 to 53 and the second semiconductor modules 71 to 73 configuring the inverter 101, and the first heat exchanger 16, which cools the DC-DC converter 21, are arranged separately. This limits deficiencies in cooling performance for the respective one of the above-described components. For example, if the electronic component 23 (the DC-DC inverter 21), the first semiconductor modules 51 to 53, and the second semiconductor modules 71 to 73 are cooled simply by the first heat exchanger 16, cooling performance may become insufficient, disadvantageously. In this case, heat generation density may be decreased by enlarging the size of each of these components. However, by improving the cooling performance for the inverter device 10 and the cooling performance for the first semiconductor modules 51 to 53, the second semiconductor modules 71 to 73, and the electronic component 23, as in the case of the present embodiment, size enlargement of the components is restrained and size enlargement of the inverter device 10 is also restrained.

(2) The first passage 24 and the second passage 42 are allowed to communicate with each other through the first vertical pipe 81 and the second vertical pipe 82. Therefore, coolant is supplied to both the first passage 24 and the second passage 42 even without being supplied separately to the first passage 24 and the second passage 42. This makes it unnecessary to arrange the supply pipe 84 and the discharge pipe 85 separately for the cooling device 41 and the first heat exchanger 16.

(3) The first passage 24 and the second passage 42 are arranged in a stacked manner. This restrains increase of the surface area of the power module 30 as viewed from above, thus restraining size enlargement of the inverter device 10.

(4) The supply port 22a and the discharge port 22b are both arranged in the first passage 24. This provides a simple sealing structure compared to a case in which the supply port 22a and the discharge port 22b are arranged in separate passages. The first passage 24 is formed by the corresponding outer surface of the housing 11 and the metal base substrate (the passage forming member). Both the supply port 22a and the discharge port 22b are arranged in the first passage 24. This facilitates connection of the coolant supply source 83 to the supply pipe 84 and the discharge pipe 85.

(5) The second passage 42 and the discharge passage 27 have a flow-reversing structure. The discharge pipe 85 is arranged adjacent to the supply pipe 84. This facilitates connection of the discharge pipe 85 and the supply pipe 84 to the coolant supply source 83.

(6) The cooling device 41 is arranged separately from the housing 11. This facilitates joint of the first semiconductor modules 51 to 53 and the second semiconductor modules 71 to 73 to the opposite surfaces of the cooling device 41, compared to a case in which the first semiconductor modules 51 to 53 and the second semiconductor modules 71 to 73 are joined to the opposite surfaces of the cooling device 41 that is formed integrally with the housing 11. This allows the cooling device 41 to be reduced in size compared to the case in which the cooling device 41 is formed integrally with the housing 11, thereby adding to the layout flexibility in the housing 11.

(7) The first fins 28 are molded integrally with the main body 12 through die casting. On the other hand, the second fins 45 are arranged separately from the cooling device 41 and provided in the cooling device 41 (the second passage 42) through brazing, for example. The fin pitch of the second fins 45 is thus small compared to the fin pitch of the first fins 28. This improves cooling performance of the cooling device 41, which cools the first semiconductor modules 51 to 53 and the second semiconductor modules 71 to 73, thus facilitating manufacture of the first heat exchanger 16, which needs less cooling performance than the cooling device 41.

(8) The metal base substrate 22, on which the DC-DC converter 21 is mounted, is used as the passage forming member. This makes it unnecessary to prepare a separate passage forming member. As a result, the first passage 24 is defined without increasing the number of components.

The above described embodiment may be modified as follows.

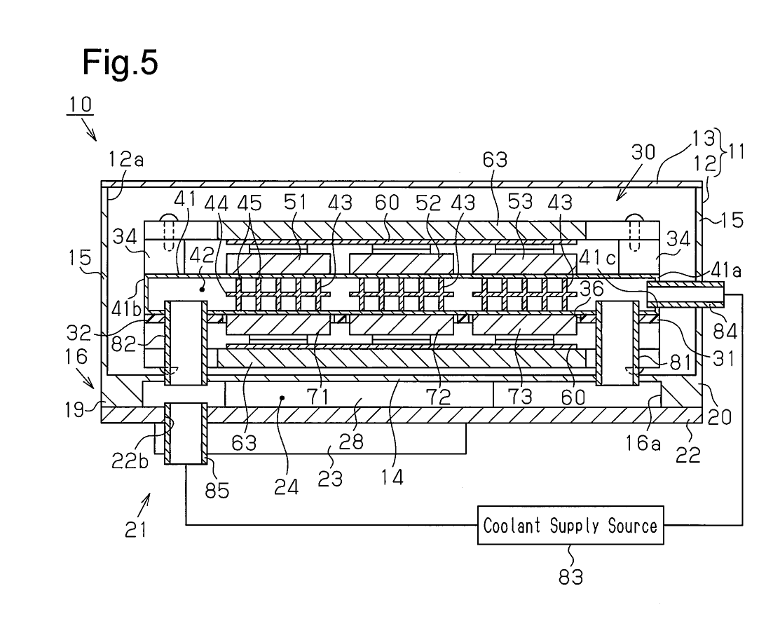

As illustrated in FIG. 5, the supply pipe 84 may be arranged in the cooling device 41. A supply port 41c is arranged in the first longitudinal end portion 41a of the cooling device 41. The supply pipe 84 is connected to the supply port 41c. Coolant is supplied into the second passage 42 through the supply pipe 84. Some of the coolant then flows into the first passage 24 via the first vertical pipe 81, while the rest of the coolant flows in the second passage 42. The coolant in the first passage 24 is discharged through the discharge pipe 85 and then re-supplied to the coolant supply source 83. The coolant in the second passage 42 flows into the first passage 24 through the second vertical pipe 82. The coolant is then discharged through the discharge pipe 85 and re-supplied to the coolant supply source 83. In this case, unlike the configuration illustrated in FIG. 2, it is unnecessary to define the supply passage 26 and the discharge passage 27 and the partition wall 25 is unnecessary. If a discharge pipe is arranged at the second longitudinal end portion 41b of the cooling device 41 in addition to the discharge pipe 85 provided in the first heat exchanger 16, the second vertical pipe 82 does not necessarily have to be provided.

In the above illustrated embodiment, the dimensions of the metal base substrate 22 may be changed as needed in such a range that the opening 12a, which is surrounded and formed by the projections 17, 18, 19, 20, is covered by the metal base substrate 22.

In the above illustrated embodiment, each of the first semiconductor modules 51 to 53 is connected in parallel with the corresponding one of the second semiconductor modules 71 to 73 to configure the single three-phase inverter. However, the embodiment is not restricted to this configuration and the first semiconductor modules 51 to 53 and the corresponding second semiconductor modules 71 to 73 may configure separate inverters.

In the above illustrated embodiment, only the first semiconductor modules 51 to 53 or the second semiconductor modules 71 to 73 may be joined to the cooling device 41. That is, semiconductor modules may be joined to only one of the opposite surfaces of the cooling device 41 in the thickness direction, either of which may be an installment surface for the semiconductor modules.

In the illustrated embodiment, as a heat generating component, the capacitor C2 arranged in the inverter device 10 may be employed. That is, the inverter device 10 does not necessarily have to include the DC-DC converter 21. Even when the inverter device 10 includes the DC-DC converter 21, the first heat exchanger 16 does not necessarily have to cool the DC-DC converter 21 as long as such cooling is unnecessary.

In the illustrated embodiment, a heat generating component may be arranged in the housing 11. Specifically, any suitable arrangement is allowed as long as the first heat exchanger 16 is thermally coupled to the heat generating component by joining the heat generating component to an inner surface of the bottom plate 14.

In the illustrated embodiment, the second passage 42 may be divided into the supply passage 26 and the discharge passage 27. In this case, the supply pipe 84 and the discharge pipe 85 are arranged in the cooling device 41.

In the illustrated embodiment, as long as cooling performance for the first semiconductor modules 51 to 53, the second semiconductor modules 71 to 73, and the electronic component 23 is ensured without employing the first fins 28 or the second fins 45, neither the first fins 28 nor the second fins 45 have to be provided.

In the illustrated embodiment, as long as the cooling performance is maintained without becoming insufficient even when the second fins 45 are molded integrally with the cooling device 41, the second fins 45 may be molded integrally with the cooling device 41.

In the illustrated embodiment, as a passage forming member, any suitable component other than the metal base substrate 22 may be employed. For example, a lid member for covering the opening 12a, which is formed in the outer surface of the bottom plate 14, may be used as the passage forming member. In this case, the metal base substrate 22 may be arranged on the lid member.

In the illustrated embodiment, the first semiconductor modules 51 to 53 and the second semiconductor modules 71 to 73 may be joined to the cooling device 41 through brazing. The first semiconductor modules 51 to 53 and the second semiconductor modules 71 to 73 may be joined to the cooling device 41 through any suitable means other than brazing, or, for example, using adhesive.

In the illustrated embodiment, the passage forming member (the metal base substrate 22) does not necessarily have to cover the entire portion of the corresponding outer surface of the bottom plate 14. The passage forming member may cover the outer surface of the bottom plate 14 in such a range that the opening 16a is closed by the passage forming member.

### DESCRIPTION OF THE REFERENCE NUMERALS

10 . . . inverter device, 11 . . . housing, 16 . . . first heat exchanger, 22 . . . metal base substrate, 22a, 41c . . . supply port, 22b . . . discharge port, 23 . . . electronic component, 24 . . . first passage, 26 . . . supply passage, 27 . . . discharge passage, 41 . . . cooling device, 42 . . . second passage, 45 . . . second fin, 51, 52, 53 . . . first semiconductor module, 71, 72, 73 . . . second semiconductor module, 81 . . . first vertical pipe, 82 . . . second vertical pipe, 84 . . . supply pipe, 85 . . . discharge pipe.

1. An inverter device comprising:
a housing;
a semiconductor module accommodated in the housing;
a first heat exchanger having a first passage defined by an outer surface of the housing and a passage forming member that covers at least a portion of the outer surface, wherein the first heat exchanger is thermally coupled to a heat generating component;
a second heat exchanger arranged in the housing, wherein the second heat exchanger has a second passage stacked on the first passage and is thermally coupled to the semiconductor module;
a supply port connected to a supply pipe for supplying coolant from a coolant supply source to the first heat exchanger or the second heat exchanger;
a discharge port connected to a discharge pipe, wherein the discharge pipe discharges coolant from the first heat exchanger or the second heat exchanger to the coolant supply source; and
a communication line that allows the first passage and the second passage to communicate with each other,
wherein the first heat exchanger and the second heat exchanger are formed separately.

2. The inverter device according to claim 1, wherein
the communication line includes a first communication line and a second communication line different from the first communication line,
one of the first passage and the second passage has a supply passage and a discharge passage, wherein the supply passage has the supply port and is connected to the first communication line, and the discharge passage has the discharge port and is connected to the second communication line, and
the other one of the first passage and the second passage and the discharge passage have a flow-reversing structure.

3. The inverter device according to claim 2, wherein
the first passage has:
a supply passage that has the supply port and is connected to the first communication line; and
a discharge passage that has the discharge port and is connected to the second communication line, and
the second passage and the discharge passage have a flow-reversing structure.

4. (canceled)

5. The inverter device according to claim 1, wherein
the first passage has a first fin molded integrally with the first heat exchanger through die casting, and
the second passage has a second fin that is formed separately from the second heat exchanger.

6. The inverter device according to claim 1, wherein
the heat generating component includes an electronic component joined to a metal base substrate, and
the metal base substrate functions also as the passage forming member.
